(19) United States
(12) Patent Application Publication
(10) Pub. No.: US 2025/0176193 A1
(43) Pub. Date: May 29, 2025

(54) MEMORY DEVICE AND METHOD OF MANUFACTURING THE SAME

(71) Applicant: Samsung Electronics Co., Ltd., Suwon-si (KR)

(72) Inventors: Changseung LEE, Suwon-si (KR); Kiyeon YANG, Suwon-si (KR); Youngjae KANG, Suwon-si (KR); Hajun SUNG, Suwon-si (KR); Wooyoung YANG, Suwon-si (KR)

(73) Assignee: Samsung Electronics Co., Ltd., Suwon-si (KR)

(21) Appl. No.: 18/636,807

(22) Filed: Apr. 16, 2024

(30) Foreign Application Priority Data
Nov. 27, 2023 (KR) 10-2023-0167150

(51) Int. Cl. H10B 63/00; H10B 63/10

(52) U.S. Cl. CPC H10B 63/845; H10B 63/10

(57) ABSTRACT

A memory device including a plurality of insulating layers, a first conductor vertically between each pair of the plurality of insulating layers, the first conductor recessed in a direction parallel to the substrate with respect to a corresponding pair of the plurality of insulating layers and defining a recess portion, the first conductor covering a portion of a surface of each of the plurality of insulating layers, a first barrier layer covering surfaces of the plurality of insulating layers and the first conductor along the recess portion, a second barrier layer extending from the first barrier layer and in contact with side surfaces of the insulating layers, a chalcogenide layer covering the first barrier layer and the second barrier layer along the recess region, and a second conductor extending to perpendicular to the substrate, wherein the second barrier layer may include a nonconductive carbon-based material may be provided.

### CROSS-REFERENCE TO RELATED APPLICATION

This application is based on and claims priority under 35 U.S.C. § 119 to Korean Patent Application No. 10-2023-0167150, filed on Nov. 27, 2023, in the Korean Intellectual Property Office, the disclosure of which is incorporated by reference herein in its entirety.

### BACKGROUND

### 1. Field

The disclosure relates to memory devices and methods of manufacturing the same.

### 2. Description of the Related Art

As electronic products tend to be light, thin, short, and small, there is an increasing demand for high integration of memory devices. A memory device having a cross-point structure has a structure in which word lines and bit lines vertically cross each other and memory cells are arranged in a region where they cross each other. This structure has an advantage of having a small memory cell on a plane.

Recently, a self-selecting memory device (SSM) that simultaneously performs as a selector and a memory device has been used in memory cells of cross-point structures. In this case, a cross-talk phenomenon occurring between a plurality of memory cells in a vertical memory structure becomes an issue.

### SUMMARY

Provided are memory devices having an improved cross-talk phenomenon and methods of manufacturing the same.

Additional aspects will be set forth in part in the description which follows and, in part, will be apparent from the description, or may be learned by practice of the presented example embodiments of the disclosure.

According to an example embodiments of the disclosure, a memory device includes a plurality of insulating layers vertically spaced apart from each other on a substrate, a first conductor vertically between each pair of the plurality of insulating layers, the first conductor recessed in a direction parallel to the substrate with respect to a corresponding pair of the plurality of insulating layers and defining a recess portion, the first conductor covering a portion of a surface of each of the plurality of insulating layers, a first barrier layer covering surfaces of the plurality of insulating layers and the first conductor along the recess portion, a second barrier layer extending from the first barrier layer and in contact with side surfaces of the insulating layers, a chalcogenide layer covering the first barrier layer and the second barrier layer along the recess portion, and a second conductor extending in a direction perpendicular to the substrate, wherein the second barrier layer may include a nonconductive carbon-based material.

The second barrier layer may include fluorinated carbon, carbon fluoride oxide, carbon nitride, or carbon oxynitride.

An atomic percentage of carbon in the fluorinated carbon may be greater than an atomic percentage of fluorine.

The first barrier layer may include a conductive carbon-based material.

The first barrier layer may include carbon, carbon nitride, or carbon silicon.

The chalcogenide layer may include a chalcogen element and at least one of Ge, As, or Sb.

The memory device may further include a third barrier layer arranged between the chalcogenide layer and the second conductor.

The third barrier layer may include carbon, carbon nitride, or carbon silicon.

According to an example embodiment of the disclosure, a method of manufacturing a memory device includes alternately stacking a plurality of first conductors and a plurality of insulating layers on a substrate, etching the plurality of first conductors and the plurality of insulating layers to define a through hole penetrating therethrough in a direction perpendicular to the substrate, etching the plurality of first conductors to define recess portions, forming first barrier layers along the recess portions and to cover surfaces of the plurality of insulating layers and the first conductors, converting portions of the first barrier layers into second barrier layers including a nonconductive carbon-based material, the portions extending in the direction perpendicular to the substrate and in contact with the insulating layers, forming a chalcogenide layer on an inner wall of the through hole, and forming a second conductor on the chalcogenide layer.

The converting of portions of the first barrier layers into the second barrier layers may use a directional plasma treatment.

The directional plasma treatment may use oxygen plasma or fluorine plasma.

The forming of the first barrier layers and the converting of the portions of the first barrier layers into the second barrier layers may be performed through a super cycle including a first cycle for forming a carbon layer and a second cycle for forming a nonconductive fluorinated carbon layer.

The first cycle may include injecting a precursor, performing a first purging process, injecting a reactant, and performing a second purging process.

The second cycle may include injecting a precursor, performing a first purging process, injecting a reactant, performing a second purging process, performing plasma treatment, and performing a third purging process.

The super cycle may be performed to perform the second cycle once after performing the first cycle a plurality of times.

The method of manufacturing a memory device may further include forming a third barrier layer arranged between the chalcogenide layer and the second conductor.

According to an example embodiment of the disclosure, a method of manufacturing a memory device includes alternately stacking a plurality of first conductors and a plurality of insulating layers on a substrate, etching the plurality of first conductors and the plurality of insulating layers to define a through hole penetrating therethrough in a direction perpendicular to the substrate, etching the plurality of first conductors to form recess portions, forming second barrier layers along the recess portions and to cover surfaces of the plurality of insulating layers and the first conductors, the second barrier layers comprising a nonconductive carbon-based material, reducing portions of the second barrier layers in contact with side surfaces of the first conductors to convert the reduced portions into first barrier layers, forming a chalcogenide layer on an inner wall of the through hole, and forming a second conductor on the chalcogenide layer.

The reducing of the portions of the second barrier layers uses a plasma treatment.

The plasma treatment may be performed using plasma including an H₂ gas, a carbon-based gas, or an inert gas.

The method of manufacturing a memory device may further include forming a third barrier layer between the chalcogenide layer and the second conductor.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 is a cross-sectional view illustrating a memory device according to an example embodiment;

FIG. 2 is an enlarged view of a portion A of FIG. 1;

FIGS. 3A to 3G are cross-sectional views illustrating a method of manufacturing a memory device according to an example embodiment;

FIG. 4 is a diagram illustrating a barrier layer conversion method according to an example embodiment;

FIGS. 5A and 5B are diagrams illustrating a barrier layer conversion method according to an example embodiment;

FIGS. 6A and 6B are diagrams illustrating a barrier layer conversion method according to an example embodiment;

FIG. 7 is a conceptual block diagram schematically showing a device architecture applicable to an electronic device according to an example embodiment;

FIG. 8 is a block diagram of a memory system according to an example embodiment; and

FIG. 9 is a block diagram illustrating a neuromorphic apparatus and an external device connected thereto according to an example embodiment.

### DETAILED DESCRIPTION

Reference will now be made in detail to some example embodiments, examples of which are illustrated in the accompanying drawings, wherein like reference numerals refer to like elements throughout. In this regard, the present example embodiments may have different forms and should not be construed as being limited to the descriptions set forth herein. Accordingly, the presented example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, memory devices and methods of manufacturing the same will be described in detail with reference to the accompanying drawings. In the following drawings, the same or similar reference numerals refer to the same or similar components, and the size of each component in the drawings may be exaggerated for clarity and convenience of description. In addition, the presented example embodiments described below are merely illustrative, and various modifications are possible from these embodiments.

Hereinafter, the term “upper portion” or “on” may also include “to be present on the top, bottom, left or right portion on a non-contact basis” as well as “to be present just on the top, bottom, left or right portion in directly contact with”. Singular expressions include plural expressions unless the context clearly means otherwise. In addition, when a part “includes” a component, this means that it may further include other components, rather than excluding other components, unless otherwise stated.

The use of the terms “a,” “an,” and “the” may correspond to both singular and plural. Unless there is a clear order or contrary description of the steps constituting the method, these steps may be performed in the appropriate order, and are not necessarily limited to the order described.

The connection or connection members of lines between the components shown in the drawings exemplarily represent functional connection and/or physical or circuit connections, and may be replaceable or represented as various additional functional connections, physical connections, or circuit connections in an actual device.

The use of all examples or illustrative terms is simply to describe technical ideas in detail, and the scope is not limited due to these examples or illustrative terms unless the scope is limited by the claims.

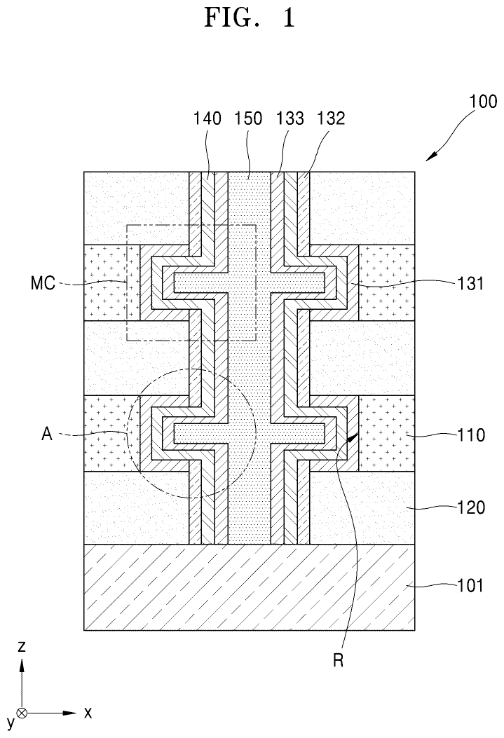

FIG. 1 is a cross-sectional view illustrating a memory device according to an example embodiment.

Referring to FIG. 1, a memory device 100 may include a substrate 101, a plurality of insulating layers 120 arranged to be vertically spaced apart from each other, a plurality of first conductors 110 arranged between the plurality of insulating layers 120, a first barrier layer 131 and a second barrier layer 132 in contact with the plurality of insulating layers 120 and the plurality of first conductors 110, a chalcogenide layer 140 arranged to be in contact with the first barrier layer 131 and the second barrier layer 132, and a second conductor 150 arranged to extend vertically to the substrate 101.

The memory device 100 may include a plurality of memory cells MC stacked vertically on the substrate 101. Each memory cell MC may include the first conductor 110, the first barrier layer 131, the second barrier layer 132, the chalcogenide layer 140, a third barrier layer 133, and the second conductor 150.

The substrate 101 may include various materials. For example, the substrate 101 may include semiconductor materials such as silicon (Si), germanium (Ge), silicon germanium (SiGe), silicon carbide (SiC), gallium arsenic (GaAs), indium arsenic (InAs), indium phosphide (InP), and insulating materials such as silicon oxide, silicon nitride, or silicon oxynitride.

The substrate 101 may further include a driving circuit region (not shown). The driving circuit region may include one or more transistors and a wiring structure electrically connected to the transistor. Each of the transistors may include a gate, a gate insulating layer, and a source/drain. The wiring structure may be arranged at an appropriate number and location according to the layout of the driving circuit region, the type and arrangement of the gate, and the like. The wiring structure may have a multilayer structure of two or more layers. For example, the wiring structure includes contacts and wiring layers electrically connected to each other, which may be sequentially stacked on the substrate. The contacts and the wiring layers may include each independently metal, conductive metal nitride, metal silicide, or a combination thereof, and may include a conductive material such as tungsten, molybdenum, titanium, cobalt, tantalum, nickel, tungsten silicide, titanium silicide, cobalt silicide, tantalum silicide, nickel silicide, or the like.

The wiring structure may include interlayer insulating layers electrically isolating each component. The interlayer insulating layers may be arranged between a plurality of transistors, a plurality of wiring layers, and/or a plurality of contacts. The interlayer insulating layers may include silicon oxide, silicon oxynitride, silicon oxynitride, or the like.

The first conductors 110 may be arranged between the plurality of insulating layers 120, respectively, to form recess portions R while covering a portion of a surface of each of the plurality of insulating layers 120. In other words, the insulating layer 120 protrudes from the first conductor 110 in a direction (X direction) parallel to an upper surface of the substrate 101, and protruding portions of the two insulating layers 120 facing each other and a side surface of the first conductor 110 may form a recess portion R. The plurality of first conductors 110 may be vertically spaced apart from each other on the substrate 101, and each of the first conductors 110 may extend in a direction parallel to the substrate 101.

A word line may be electrically connected to each of the plurality of first conductors 110. The first conductors 110 may include a metal material having excellent electrical conductivity. For example, the first conductors 110 may include TIN, Au, or the like. However, example embodiments are not limited thereto.

The insulating layers 120 may be arranged to be spaced apart from each other in a direction (z direction) perpendicular to the substrate 101, and each insulating layer 120 may extend in a direction (x direction) parallel to the substrate 101. The insulating layer 120 is for insulation between the adjacent first conductors 110, and may include, for example, silicon oxide, silicon nitride, or the like. However, example embodiments are not limited thereto.

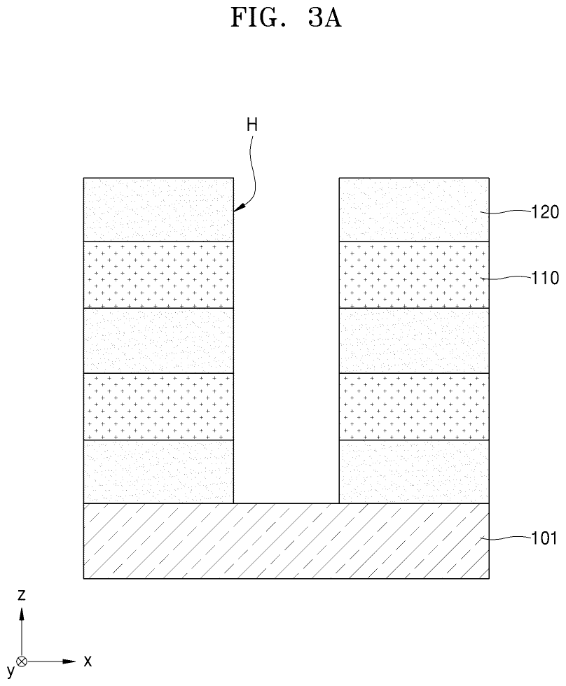

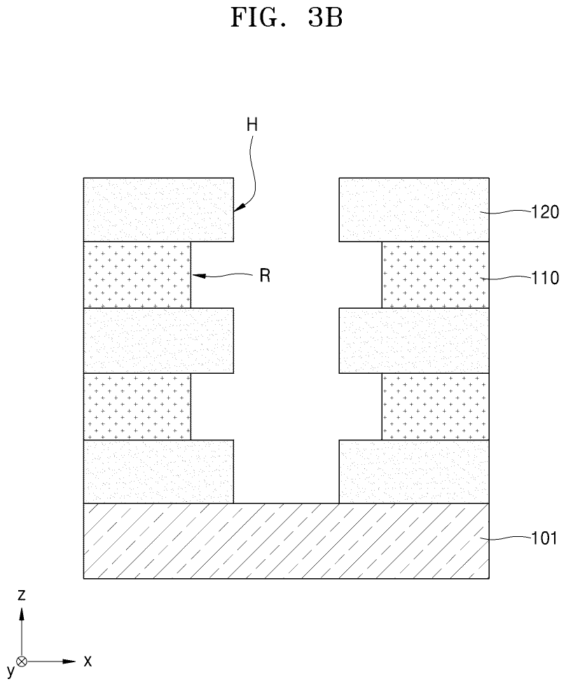

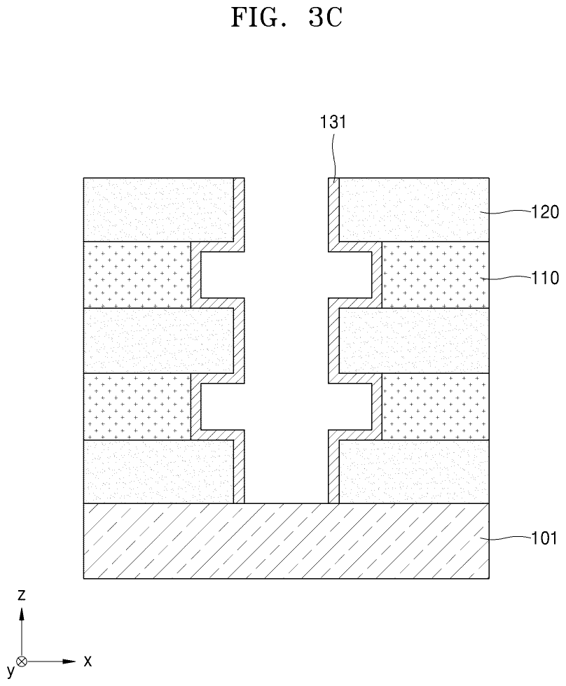

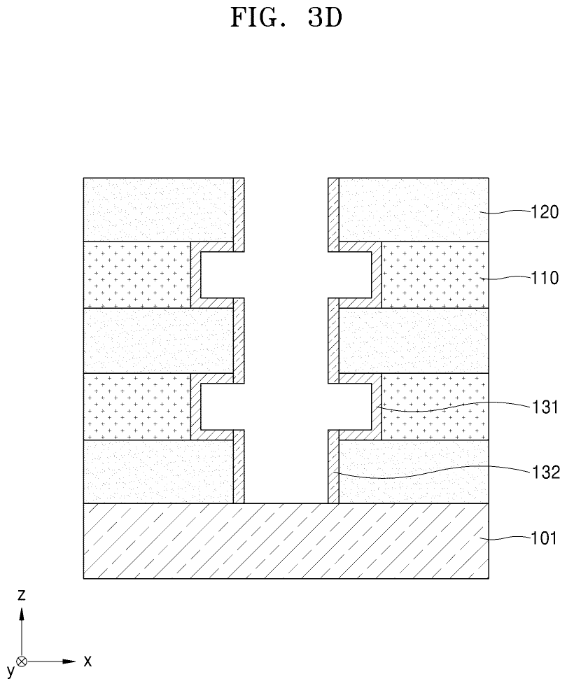

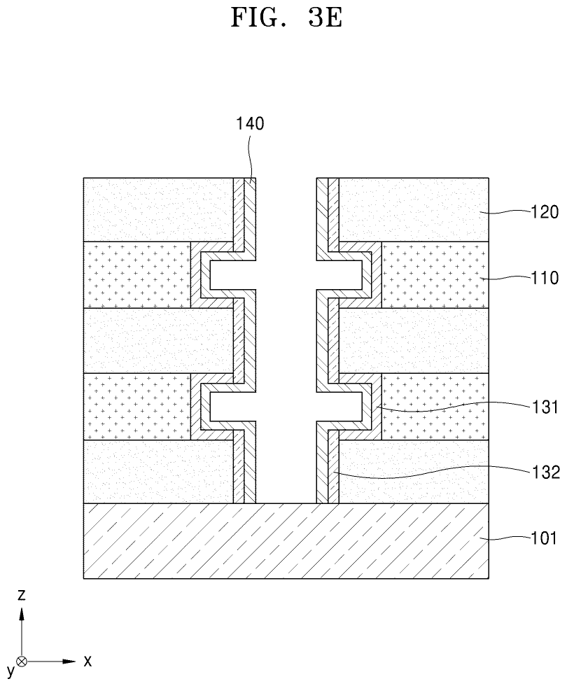

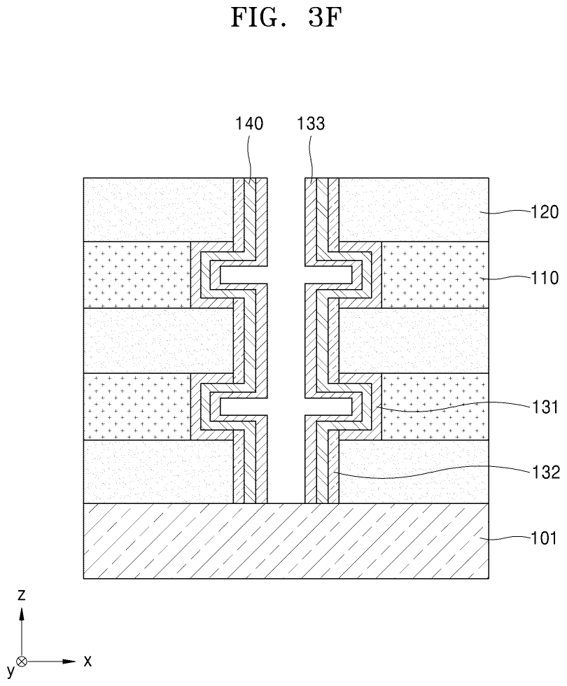

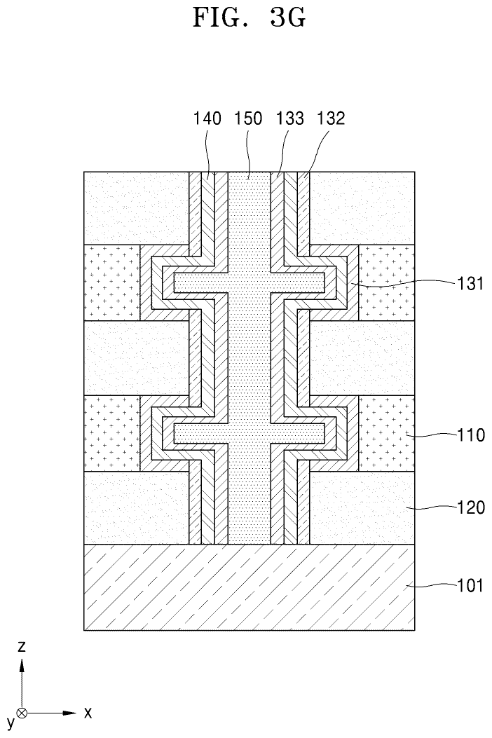

A through hole (H in FIG. 3A) may be formed in the plurality of first conductors 110 and the plurality of insulating layers 120 in a direction perpendicular to the substrate 101 (z direction). The through hole (H in FIG. 3A) may be formed to have, for example, a circular cross section. A first barrier layer 131, a second barrier layer 132, a chalcogenide layer 140, the third barrier layer 133, and a second conductor 150 may be sequentially provided on the inner wall of the through hole (H in FIG. 3A).

The chalcogenide layer 140 may cover the first barrier layer 131 along the recess portion R. The chalcogenide layer 140 may be in contact with the second barrier layer 132. The chalcogenide layer 140 may be spaced apart from the insulating layer 120 with the second barrier layer 132 therebetween. The chalcogenide layer 140 may cover the first barrier layer 131 and the second barrier layer 132 on an inner wall of the through hole H (see FIG. 3A). The chalcogenide layer 140 may be in a cylindrical shape surrounding the third barrier layer 133 and the second conductor 150. The chalcogenide layer 140 may extend in a direction perpendicular to the substrate.

The chalcogenide layer 140 may include a chalcogenide material exhibiting nonvolatile memory characteristics. The chalcogenide layer 140 may include a chalcogen element and at least one of Ge, As, or Sb. Here, the chalcogen element may include at least one of Se or Te.

The chalcogenide layer 140 may include a material (e.g., a GeAsSe-based material) having a threshold switching characteristic. In this case, the chalcogenide layer 140 may exhibit nonvolatile memory characteristics by changing the threshold switching voltage through a negative bias in an amorphous state of a chalcogenide material.

The chalcogenide layer 140 may include a material (e.g., GeSbTe) having a phase change characteristic. In this case, nonvolatile memory characteristics may be exhibited by changing the chalcogenide material into a crystalline or amorphous structure through joule heat to generate a resistance difference. The chalcogenide layer 140 may further include a material (e.g., a GeAsSe-based material) having an ovonic threshold switching (OTS) characteristic.

The first barrier layer 131 may cover surfaces of the plurality of insulating layers 120 and the first conductors 110 along the recess portions R. The first barrier layer 131 may be arranged to be in contact with the chalcogenide layer 140.

The first barrier layer 131 may serve to mitigate or prevent mixing between the metal material of the first conductor 110 and the chalcogenide material of the chalcogenide layer 140. When the first conductor 110 including the metal material and the chalcogenide layer 140 including the chalcogenide material are in direct contact with each other, mixing of the metal material and the chalcogenide material may occur and characteristics of the memory device may be deteriorated.

The first barrier layer 131 may include a carbon-based material. The first barrier layer 131 may include, for example, carbon. However, example embodiments are not limited thereto, and the first barrier layer 131 may include, for example, carbon nitride or carbon silicon.

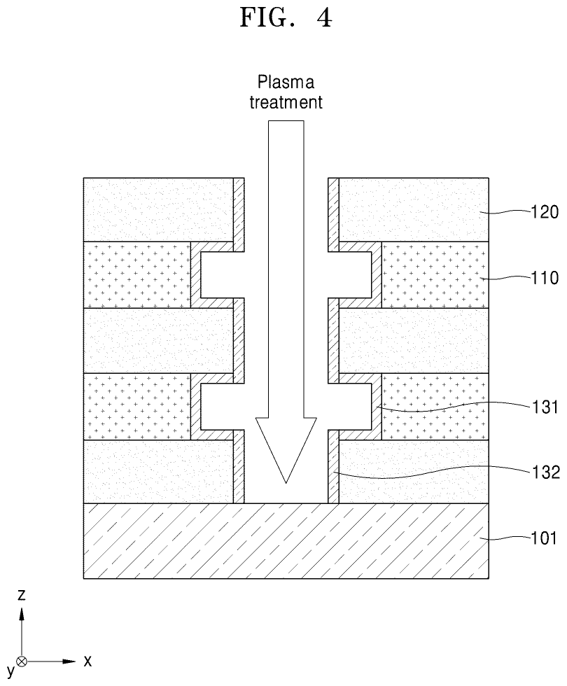

The second barrier layer 132 may be formed by converting a portion of the first barrier layer 131. A method of forming the second barrier layer 132 will be described later with reference to FIGS. 4 to 6B. The second barrier layer 132 may extend from the first barrier layer 131 and may be arranged to be in contact with a side surface of the insulating layer 120. The second barrier layer 132 may be arranged on a side surface of the insulating layer 120. The second barrier layer 132 may be arranged between the insulating layer 120 and the chalcogenide layer 140.

The second barrier layer 132 may include a nonconductive carbon-based material. The second barrier layer 132 may include, for example, a nonconductive carbon layer. However, example embodiments are not limited thereto, and the second barrier layer 132 may include, for example, a nonconductive carbon nitride layer or a nonconductive carbon silicon layer.

The second barrier layer 132 including the nonconductive carbon-based material may be arranged on the side surface of the insulating layer 120 to electrically isolate the adjacent memory cells MC. That is, the second barrier layer 132 arranged on the side surface of the insulating layer 120 includes a nonconductive carbon-based material, thereby mitigating or preventing a cross-talk from occurring between the memory cells MC.

A second conductor 150 is provided on the chalcogenide layer 140. The second conductor 150 may be provided to fill the through hole H (see FIG. 3A) formed inside the chalcogenide layer 140. The second conductor 150 may vertically extend from the substrate 101. In some example embodiments, the second conductor 150 may be formed in a cylindrical shape, and in this case, a filling insulation layer (not shown) may be provided in the through hole (H in FIG. 3A) inside the second conductor 150. Like the first conductor 110, the second conductor 150 may include a metal material having excellent electrical conductivity. A bit line may be electrically connected to the second conductor 150.

A third barrier layer 133 may be provided between the chalcogenide layer 140 and the second conductor 150. The third barrier layer 133 may be formed in a cylindrical shape surrounding the second conductor 150. The third barrier layer 133 may vertically extend from the substrate 101.

The third barrier layer 133 may serve to prevent mixing between the metal material of the second conductor 150 and the chalcogenide material of the chalcogenide layer 140. The third barrier layer 133 may include a carbon-based material. The third barrier layer 133 may include, for example, a carbon layer. However, example embodiments are not limited thereto, and the third barrier layer 133 may include, for example, a carbon nitride layer or a carbon silicon layer.

In the memory device 100 according to the present example embodiment, a portion of the first barrier layer 131 is converted into the second barrier layer 132 including a nonconductive carbon-based material, thereby mitigating or preventing a cross-talk from occurring between the memory cells MC. In addition, it is possible to realize the high integration of the memory device 100 by a vertical memory structure in which memory cells MC are vertically stacked on the substrate 101.

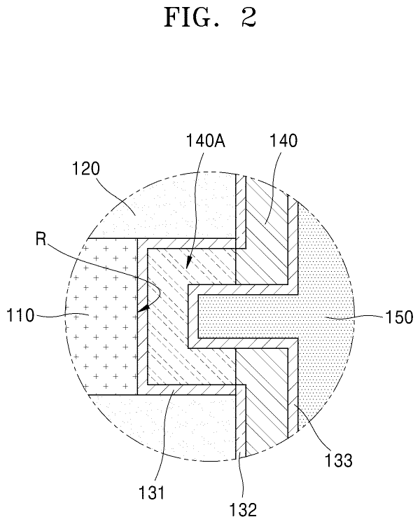

FIG. 2 is an enlarged view of a portion A of FIG. 1.

Referring to FIG. 2, the chalcogenide layer 140 may cover the first barrier layer 131 along the recess portion R, and may be in contact with the second barrier layer 132. A portion of the chalcogenide layer 140 covering the first barrier layer 131 along the recess portion R may be referred to as a program region 140A.

The program region 140A is a region that performs SET and RESET operations by changing a resistance. The program region 140A may be in contact with the first barrier layer 131 and third barrier layer 133, and between the first barrier layer 131 and third barrier layer 133. In the memory device 100 according to the present example embodiment, because the program region 140A is arranged along the recess portion R, electrical interference between adjacent program regions 140A may be blocked.

FIGS. 3A to 3G are cross-sectional views illustrating a method of manufacturing a memory device according to an example embodiment. In FIGS. 3A to 3G, the same reference numerals as those in FIG. 1 denote identical members, and a detailed description thereof will be omitted.

Referring to FIG. 3A, a plurality of insulating layers 120 and a plurality of first conductors 110 are alternately stacked on a substrate 101 in a direction perpendicular to the substrate 101 (z-axis direction). The substrate 101 may include various materials.

Each of the plurality of first conductors 110 extends parallel to the substrate 101, and each of the plurality of insulating layers 120 extends parallel to the substrate 101. The first conductors 110 may include a metal material having excellent electrical conductivity. For example, the first conductor 110 may include TIN, Au, or the like, but is not limited thereto. The insulating layer 120 may include, for example, silicon oxide, silicon nitride, or the like. However, example embodiments are not limited thereto.

Subsequently, a through hole H is formed by etching the plurality of first conductors 110 and the plurality of insulating layers 120 until the substrate 101 is exposed. The through hole H may be formed to extend in a direction perpendicular to the substrate 101 (z-axis direction). The through hole H may be formed to have, for example, a circular cross section. The top surface of the substrate 101 may be exposed through the bottom of the through hole H, and side surfaces of the first conductors 110 and the insulating layers 120 may be exposed through the sidewalls (e.g., side boundaries) of the through hole H.

Referring to FIG. 3B, recess portions R are formed by etching the inner side surfaces of the first conductors 110. The protruding side surfaces of the two facing insulating layers 120 and the etched side surfaces of the first conductor 110 may form the recess portions R.

Referring to FIG. 3C, a first barrier layer 131 is formed to cover surfaces of the plurality of insulating layers 120 and the first conductors 110 along the recess portions R. The first barrier layer 131 may serve to mitigate or prevent mixing between the metal material of the first conductor 110 and the chalcogenide material of the chalcogenide layer 140. The first barrier layer 131 may include a carbon-based material.

Referring to FIG. 3D, in the first barrier layer 131, portions extending in a direction perpendicular to the substrate and in contact with the insulating layers 120 are converted into the second barrier layers 132. The second barrier layer 132 may include a nonconductive carbon-based material. Some example methods of converting portions of the first barrier layer 131 into the second barrier layers 132 will be explained later.

Referring to FIG. 3E, the chalcogenide layer 140 is formed on an inner wall of the through hole H. The chalcogenide layer 140 may be formed to cover the first barrier layer 131 and the second barrier layer 132 along the recess portion R. The chalcogenide layer 140 may have a cylindrical shape and may be formed to extend in a direction perpendicular to the substrate. The chalcogenide layer 140 may include a chalcogenide material exhibiting nonvolatile memory characteristics.

Referring to FIG. 3F, the third barrier layer 133 may be formed to cover the chalcogenide layer 140. The third barrier layer 133 may be formed in a cylindrical shape surrounding the second conductor 150, which is to be formed later. The third barrier layer 133 may vertically extend from the substrate 101. The third barrier layer 133 may serve to mitigate or prevent mixing between the metal material of the second conductor 150 and the chalcogenide material of the chalcogenide layer 140.

Referring to FIG. 3G, the second conductor 150 is formed to cover the third barrier layer 133. The second conductor 150 may be provided to fill the through hole H formed inside the chalcogenide layer 140. The second conductor 150 may be provided to vertically extend from the substrate 101. Meanwhile, the second conductor 150 may be formed in a cylindrical shape, and in this case, a filling insulation layer (not shown) may be provided in the through hole H inside the second conductor 150. The second conductors 150 may include a metal material having excellent electrical conductivity.

FIG. 4 is a diagram illustrating a barrier layer conversion method according to an example embodiment.

FIG. 4 is an example illustrating a method of converting the first barrier layer 131 of FIG. 3D into the second barrier layer 132. Referring to FIG. 4, a portion of the first barrier layer 131 may be converted into the second barrier layer 132 through the plasma treatment. That is, a portion of the first barrier layer 131 including a conductive carbon-based material may be converted into the second barrier layer 132 including a nonconductive carbon-based material.

The plasma treatment is performed using directional plasma. The plasma may be, for example, oxygen plasma or fluorine plasma. The second barrier layer 132 converted through the plasma treatment may include a nonconductive carbon-based material. The second barrier layer 132 may include, for example, fluorinated carbon, carbon oxyfluoride, carbon nitride, or carbon oxynitride.

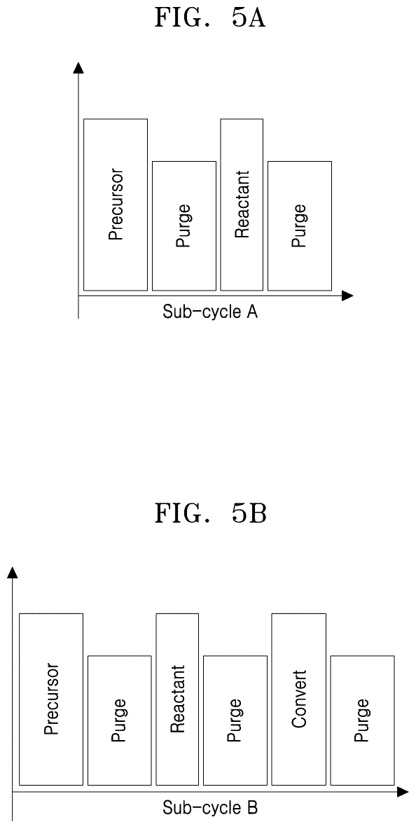

FIGS. 5A and 5B are diagrams illustrating a barrier layer conversion method according to an example embodiment.

FIGS. 5A and 5B are examples illustrating a method of converting the first barrier layer 131 of FIG. 3D into the second barrier layer 132. FIGS. 5A and 5B are diagrams respectively illustrating a sub-cycle A and a sub-cycle B that constitute a super-cycle for barrier layer conversion. The sub-cycle A may be referred to as a first cycle, and the sub-cycle B may be referred to as a second cycle.

Referring to FIG. 5A, the first barrier layer 131 including a carbon-based material may be formed to cover surfaces of the plurality of insulating layers 120 and the first conductors 110 through a first cycle. For example, in the first cycle, a precursor including vaporized gaseous carbon is first injected into a chamber of a deposition apparatus. The precursor may be adsorbed on the side surfaces of the plurality of insulating layers 120 and the first conductors 110. The precursor may include a 12yclopentadiene-based material or an aniline-based material. However, this is only an example. According to some example embodiments, precursors may include a variety of materials.

Thereafter, when a purging process is performed by injecting purging gas into the chamber, the precursors not adsorbed on the side surfaces of the plurality of insulating layers 120 and the first conductors 110 are discharged to the outside.

When a reactant is injected into the chamber after the purging process is completed, the precursors adsorbed on the side surfaces of the plurality of insulating layers 120 and the first conductors 110 react with the reactant, thereby forming the plurality of first barrier layers 131 including a carbon-based material on the side surfaces of the plurality of insulating layers 120 and the first conductors 110. The reactant may include, for example, H₂ gas or NH₃ gas, etc. Thereafter, through a purging process, reaction residues and reactants remaining in the chamber are discharged to the outside.

Referring to FIG. 5B, through the second cycle, the first barrier layer 131 is formed to cover the surfaces of the plurality of insulating layers 120 and the first conductors 110, and then the portion of the first barrier layer 131 extending in a direction perpendicular to the substrate and contacting the insulating layer 120 is converted into the second barrier layer 132.

For example, in the second cycle, a precursor including vaporized gaseous carbon is first injected into the chamber of the deposition apparatus. The precursor may be adsorbed on the side surfaces of the plurality of insulating layers 120 and the first conductors 110. The precursor may include a cyclopentadien-based material or an aniline-based material. However, this is only an example. According to some example embodiments, precursors may include a variety of materials.

Thereafter, when a purging process is performed by injecting purging gas into the chamber, the precursors not adsorbed on the side surfaces of the plurality of insulating layers 120 and the first conductors 110 are discharged to the outside.

When a reactant is injected into the chamber after the purging process is completed, the precursors adsorbed on the side surfaces of the plurality of insulating layers 120 and the first conductors 110 react with the reactant, thereby forming the first barrier layers 131 including a carbon-based material on the side surfaces of the plurality of insulating layers 120 and the first conductors 110. The reactant may include, for example, H₂ gas or NH₃ gas, etc. Thereafter, through a purging process, reaction residues and reactants remaining in the chamber are discharged to the outside.

Therefore, through the plasma treatment, in the first barrier layer 131, portions extending in a direction perpendicular to the substrate and in contact with the insulating layers 120 are converted into the second barrier layers 132. The plasma treatment is performed using directional plasma. The plasma may be, for example, oxygen plasma or fluorine plasma. The second barrier layer 132 converted through the plasma treatment may include a nonconductive carbon-based material. The second barrier layer may include fluorinated carbon, carbon fluoride oxide, carbon nitride, or carbon oxynitride. Thereafter, through a purging process, the material remaining in the chamber is discharged to the outside.

To form the first barrier layer 131 and the second barrier layer 132, for example, a super cycle including the first cycle of forming a carbon layer and a second cycle of forming a fluorinated carbon layer may be used. The super cycle may perform, for example, the second cycle once after performing the first cycle twice. The super cycle may perform, for example, the second cycle once after performing the first cycle three times. The number of respective cycles of the first cycle and the second cycle constituting the super cycle may determine the atomic percentage of carbon and the atomic percentage of fluorine of the fluorinated carbon constituting the second barrier layer 132. As the number of times of the first cycle constituting the super cycle becomes greater than the number of times of the second cycle constituting the super cycle, the atomic percentage of carbon in the fluorinated carbon may be greater than the atomic percentage of fluorine. When the atomic percentage of carbon in fluorinated carbon is greater than the atomic percentage of fluorine therein, solid fluorinated carbon may be made.

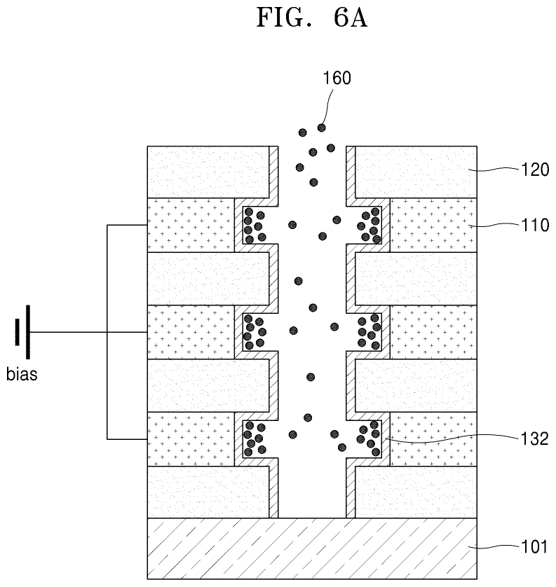

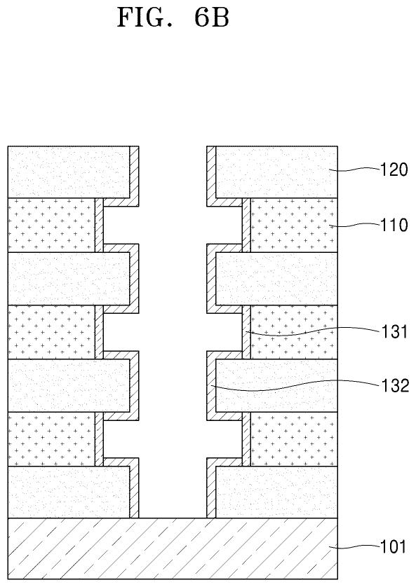

FIGS. 6A and 6B are diagrams illustrating a barrier layer conversion method according to an example embodiment. Before the processes of FIGS. 6A and 6B, the processes described with reference to FIGS. 3A and 3B may be performed, and after the processes of FIGS. 6A and 6B, the processes described with reference to FIGS. 3E and 3G may be performed.

Referring to FIG. 6A, a second barrier layer 132 is formed to cover surfaces of the plurality of insulating layers 120 and the first conductors 110 along the recess portions R. The second barrier layer 132 may include a nonconductive carbon-based material. The second barrier layer 132 may include, for example, fluorinated carbon.

Thereafter, when a bias is applied to the first conductor 110 after plasma treatment, ions 160 in the plasma are mainly collected around the first conductor 110. The plasma may include, for example, an H₂ gas, a carbon-based gas, or an inert gas. The carbon-based gas may include, for example, hydrocarbons (methane, ethane, propane, butane, etc.) or carbon nitride. The plasma treatment may be performed using a plasma that is not directional or weak.

Referring to FIG. 6B, the first barrier layer 131 may be formed by reducing a portion of the second barrier layer 132 through plasma. For example, when the second barrier layer 132 includes fluorinated carbon, the reduced first barrier layer 131 may include carbon. The first barrier layer 131 may be formed on a portion of the first conductor 110 which is in contact with the side surface thereof. The portion of the second barrier layers is reduced to the first barrier layer 131 through a plasma treatment, which uses plasma including, for example, an H₂ gas, a carbon-based gas, or an inert gas.

The memory device 100 according to the embodiment described above may be used for data storage in various electronic devices.

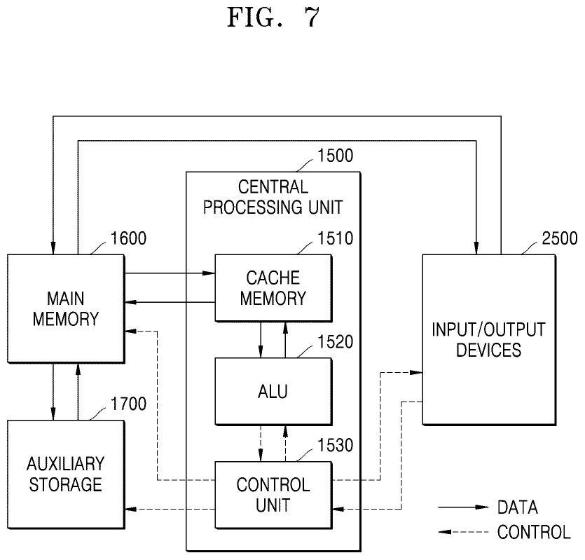

FIG. 7 is a conceptual diagram schematically showing a device architecture applicable to an electronic device according to an example embodiment.

Referring to FIG. 7, a cache memory 1510, an ALU 1520, and a control unit 1530 may configure a Central Processing Unit (CPU) 1500, and the cache memory 1510 may include a static random access memory (SRAM). Apart from the CPU 1500, a main memory 1600, an auxiliary storage 1700, and input/output devices 2500 may be provided. The main memory 1600 may include a DRAM device, and the auxiliary storage 1700 may include the memory device 100 described above. In some cases, the device architecture may be implemented in a form in which computing unit elements and memory unit elements are adjacent to each other in one chip without division of sub-units.

The memory device 100 according to the example embodiment described above may be implemented as a chip-type memory block and used as a neuromorphic computing platform, or may be used to configure a neural network.

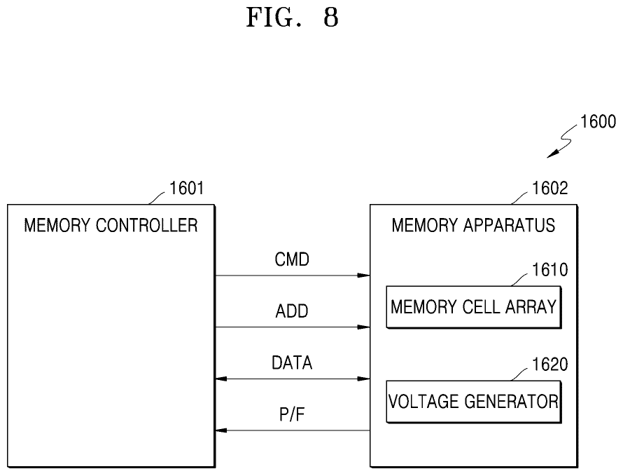

FIG. 8 is a block diagram of a memory system according to an example embodiment.

Referring to FIG. 8, a memory system (e.g., main memory in FIG. 7) 1600 may include a memory controller 1601 and a memory device 1602. The memory controller 1601 performs a control operation on the memory device 1602, and for example, the memory controller 1601 provides an address ADD to the memory device 1602 and a command CMD for performing programming (or writing), reading, and/or erasing operations on the memory device 1602. In addition, data for programming operations and read data may be transmitted between the memory controller 1601 and the memory device 1602.

The memory device 1602 may include a memory cell array 1610 and a voltage generator 1620. The memory cell array 1610 may include a plurality of memory cells, and may include the memory device 100 according to the embodiment described above.

The memory controller 1601 may include a processing circuit such as hardware including a logical circuit, a hardware/software combination such as processor execution software, or a combination thereof. For example, the processing circuit may be a central processing unit (CPU), an arithmetic logic unit (ALU), a digital signal processor, a microcomputer, a field programmable gate array (FPGA), a system-on-chip (SoC), a programmable logic unit, a microprocessor, and an application-specific integrated circuit (ASIC), but is not limited thereto. The memory controller 1601 may operate in response to a request from a host (not shown) and may be configured to convert the memory controller 1601 to a special purpose controller by accessing the memory device 1602 and controlling the control operations (e.g., write/read operations) discussed above. The memory controller 1601 may generate an address ADD and a command CMD for performing a programming/read/erase operation on the memory cell array 1610. Furthermore, in response to a command from the memory controller 1601, the voltage generator 1620 (e.g., a power circuit) may generate a voltage control signal for controlling the voltage level of the word line for data programming or data reading in the memory cell array 1610.

In addition, the memory controller 1601 may perform a determination operation on data read from the memory device 1602. For example, from data read from memory cells, the number of on-cells and/or off-cells may be determined. The memory device 1602 may provide a pass/fail signal P/F to the memory controller 1601 according to a read result of the read data. The memory controller 1601 may control write and read operations of the memory cell array 1610 by referring to the pass/fail signal P/F.

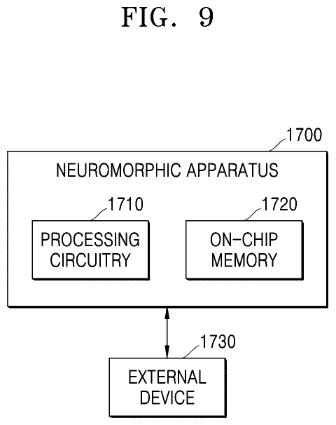

FIG. 9 is a block diagram illustrating a neuromorphic apparatus and an external device connected thereto according to an example embodiment.

Referring to FIG. 9, the neuromorphic apparatus (e.g., auxiliary storage in FIG. 7) 1700 may include a processing circuitry 1710 and/or an on-chip memory 1720. The neuromorphic apparatus 1700 may include the memory device 100 according to the example embodiment described above.

In some example embodiments, the processing circuitry 1710 may be configured to control a function for driving the neuromorphic apparatus 1700. For example, the processing circuitry 1710 may be configured to control the neuromorphic apparatus 1700 by executing a program stored in the on-chip memory 1720. In some example embodiments, the processing circuitry may include hardware such as a logic circuit, a hardware/software combination such as a processor executing software, or a combination thereof. For example, the processor may include, but is not limited to, a central processing unit (CPU), a graphics processing unit (GPU), an application processor (AP) included in the neuromorphic apparatus 1700, an arithmetic logic unit (ALU), a digital signal processor, a microcomputer, a field programmable gate array (FPGA), a system-on-chip (SoC), a programmable logic unit, a microprocessor, an application-specific integrated circuit (ASIC), or the like. In some example embodiments, the processing circuitry 1710 may be configured to read/write various data with respect to an external device 1730, and/or to execute the neuromorphic apparatus 1700 using the read/written data. In some embodiments, the external device 1730 may include an external memory and/or a sensor array having an image sensor (e.g., a CMOS image sensor circuit).

In some example embodiments, the neuromorphic apparatus of FIG. 9 may be applied to a machine learning system. Machine learning systems may use various artificial network neural network structure and processing model such as convolutional neural networks (CNNs), deconvolutional neural networks, long short-term memory (LSTM) units, and/or recurrent neural networks (RNNs) selectively including gated recurrent units (GRUs), stacked neural networks (SNNs), state-space dynamic neural networks (SSDNNs), deep belief networks (DBNs), generative adversarial networks (GANs), and restricted Boltzmann machines (RPMs).

Alternatively or additionally, these machine learning systems may include other forms of machine learning models, for example, linear and/or logistic regression, statistical clustering, Bayesian classification, decision trees, dimensional reduction such as principal component analysis, expert systems, and/or ensemble such as random forests, or a combination thereof. These machine learning models may be used to provide a variety of services and/or applications, for example, image classification services, biometric or biometric data-based user authentication services, Advanced Driver Assistance System (ADAS) services, voice assistant services, and automatic voice recognition (ASR) services may be executed by an electronic device.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Memory devices and methods of manufacturing the same according to some example embodiments have been described with reference in the drawings. According to the example embodiments, because the memory device includes a recess portion, a cross-talk phenomenon occurring between a plurality of memory cells may be improved.

According to the example embodiments, the memory device manufacturing method may prevent cross-talk from occurring between adjacent memory cells MC by converting a portion of the first barrier layer into a second barrier layer including a nonconductive carbon-based material.

It should be understood that some example embodiments described herein should be considered in a descriptive sense only and not for purposes of limitation. Descriptions of features or aspects within each example embodiment should typically be considered as available for other similar features or aspects in other example embodiments. While one or more example embodiments have been described with reference to the figures, it will be understood by those of ordinary skill in the art that various changes in form and details may be made therein without departing from the spirit and scope as defined by the following claims.

What is claimed is:

1. A memory device comprising:
a plurality of insulating layers vertically spaced apart from each other on a substrate;
a first conductor vertically between each pair of the plurality of insulating layers, the first conductor recessed in a direction parallel to the substrate with respect to a corresponding pair of the plurality of insulating layers and defining a recess portion, the first conductor covering a portion of a surface of each of the plurality of insulating layers;
a first barrier layer covering surfaces of the plurality of insulating layers and the first conductor along the recess portion;
a second barrier layer extending from the first barrier layer and in contact with side surfaces of the insulating layers;
a chalcogenide layer covering the first barrier layer and the second barrier layer along the recess portion; and
a second conductor extending in a direction perpendicular to the substrate, wherein
the second barrier layer comprises a nonconductive carbon-based material.

2. The memory device of claim 1, wherein the second barrier layer comprises fluorinated carbon, carbon fluoride oxide, carbon nitride, or carbon oxynitride.

3. The memory device of claim 2, wherein an atomic percentage of carbon in the fluorinated carbon is greater than an atomic percentage of fluorine.

4. The memory device of claim 1, wherein the first barrier layer comprises a conductive carbon-based material.

5. The memory device of claim 4, wherein the first barrier layer comprises carbon, carbon nitride, or carbon silicon.

6. The memory device of claim 1, wherein the chalcogenide layer comprises a chalcogen element and at least one of Ge, As, or Sb.

7. The memory device of claim 1, further comprising:
a third barrier layer between the chalcogenide layer and the second conductor.

8. The memory device of claim 7, wherein the third barrier layer comprises carbon, carbon nitride, or carbon silicon.

9. A method of manufacturing a memory device, the method comprising:
alternately stacking a plurality of first conductors and a plurality of insulating layers on a substrate;
etching the plurality of first conductors and the plurality of insulating layers to define a through hole penetrating therethrough in a direction perpendicular to the substrate;
etching the plurality of first conductors to define recess portions;
forming first barrier layers along the recess portions and to cover surfaces of the plurality of insulating layers and the first conductors;
converting portions of the first barrier layers into second barrier layers including a nonconductive carbon-based material, the portions extending in the direction perpendicular to the substrate and in contact with the insulating layers;
forming a chalcogenide layer on an inner wall of the through hole; and
forming a second conductor on the chalcogenide layer.

10. The method of claim 9, wherein the converting of portions of the first barrier layers into the second barrier layers uses a directional plasma treatment.

11. The method of claim 10, wherein the directional plasma treatment uses oxygen plasma or fluorine plasma.

12. The method of claim 9, wherein the forming of the first barrier layers and the converting of the portions of the first barrier layers into the second barrier layers are performed through a super cycle including a first cycle for forming a carbon layer and a second cycle for forming a nonconductive fluorinated carbon layer.

13. The method of claim 12, wherein the first cycle comprises:
injecting a precursor;
performing a first purging process;
injecting a reactant; and
performing a second purging process.

14. The method of claim 12, wherein the second cycle comprises:
injecting a precursor;
performing a first purging process;
injecting a reactant;
performing a second purging process;
performing plasma treatment; and
performing a third purging process.

15. The method of claim 12, wherein the super cycle is performed to perform the second cycle once after performing the first cycle a plurality of times.

16. The method of claim 9, further comprising:
forming a third barrier layer between the chalcogenide layer and the second conductor.

17. A method of manufacturing a memory device, the method comprising:
alternately stacking a plurality of first conductors and a plurality of insulating layers on a substrate;
etching the plurality of first conductors and the plurality of insulating layers to define a through hole penetrating therethrough in a direction perpendicular to the substrate;
etching the plurality of first conductors to form recess portions;
forming second barrier layers along the recess portions and to cover surfaces of the plurality of insulating layers and the first conductors, the second barrier layers comprising a nonconductive carbon-based material;
reducing portions of the second barrier layers in contact with side surfaces of the first conductors to convert the reduced portions into first barrier layers;
forming a chalcogenide layer on an inner wall of the through hole; and
forming a second conductor on the chalcogenide layer.

18. The method of claim 17, wherein the reducing of the portions of the second barrier layers uses a plasma treatment.

19. The method of claim 18, wherein the plasma treatment is performed using plasma comprising an H₂ gas, a carbon-based gas, or an inert gas.

20. The method of claim 17, further comprising:
forming a third barrier layer between the chalcogenide layer and the second conductor.
